(19) United States
(12) Patent Application Publication
(10) Pub. No.: US 2026/0251690 A1
(43) Pub. Date: Aug. 27, 2026

(54) Voltage Testing and Display System with Partial Discharge Detector

(71) Applicant: Dipl.-Ing. H. Horstmann GmbH, Heiligenhaus (DE)

(72) Inventors: Holger WÜRSIG, Duisburg (DE); Axel STAUBACH, Dorsten (DE)

(21) Appl. No.: 19/547,205

(22) Filed: Feb. 23, 2026

(30) Foreign Application Priority Data
Feb. 25, 2025 (DE) 10 2025 107 113.6

(51) Int. Cl. G01R 31/14

(52) U.S. Cl. CPC G01R 31/14

(57) ABSTRACT

A voltage testing and display system comprises a voltage display and a partial discharge detector for connection to an electrical conductor via a voltage divider, wherein the voltage divider consists of a coupling capacitor and a circuit impedance means, wherein the circuit impedance means is a series connection of a capacitive balancing element and an ohmic resistor, or a series connection of a capacitive balancing element with an inductive resistor, wherein both the voltage display and the partial discharge detector receive the measurement voltage dropping across the circuit impedance means as their input voltage.

The invention relates to a voltage testing and display system comprising a partial discharge detector, in particular for voltages in energy distribution systems.

Voltage testing and display systems for testing the presence of a voltage, and a corresponding display, are known from the prior art. In particular in high and extra-high voltage engineering, such systems are known as VDIS. Typically, these use a purely capacitive voltage divider, a measuring voltage being tapped at one of its capacitors. If the measuring voltage does not exceed a limit value, the corresponding conductor is displayed as voltage-free.

Partial discharges can occur in electrical insulations, in the case of high electric field strengths, if the insulation has a defect, for example if the insulation has an air inclusion, other inclusions or cracks. Partial discharges are small, spatially limited electrical discharges that occur when a critical electric field strength is exceeded in the cavities or inclusions in the insulation, for example in so-called blowholes. Such discharges cause a short, high-frequency pulse in the affected conductor. Partial discharges of this kind occur, for example, in voltage systems with voltages of more than 1000 volts, such as in energy distribution systems, or in rotating machines such as generators or electrical converters, and thus in systems of less than 1000 volts.

In the case of prolonged exposure or repeated occurrences in such a cavity, the discharges can damage the insulation and subsequently lead to a complete breakdown, causing the insulation to fail and high voltages and currents to break through into an electrical conductor adjacent to the faulty cable. When manufacturing new switchgear equipment, the insulation of the facility is tested for partial discharges before it is used at its place of operation.

For the continuous detection of partial discharges in cables, in the standard setup the voltage of the cable is coupled out to a measuring system using a four-pole outcoupling device, the measuring system being provided and suitable for detecting partial discharges on the basis of the outcoupled signal. Alternatively, in order to detect partial discharges in a cable, a soft magnetic ring can be placed around the cable as a sensor, so that the magnetic field arising due to the high-frequency current pulse during partial discharges generates a measurable voltage pulse in the sensor or at a measuring impedance means connected thereto.

From DE 101 34 790 A1 a testing device for medium and high-voltage switchgear equipment is known which, in addition to a voltage testing unit, provides a partial discharge testing unit that can be connected to the coupling electrode of a voltage divider, and means for supplying low-frequency signal components detected via the coupling electrode to the voltage testing unit, and simultaneously high-frequency signal components detected via the coupling electrode to the partial discharge testing unit. In this case, the measuring voltage is low-pass filtered for the voltage testing unit and high-pass filtered for the partial discharge testing unit.

However, a simpler measuring arrangement is advantageous for the continuous testing of partial discharges during operation.

One aspect of the invention relates to a voltage testing and display device for galvanic coupling to a coupling capacitor which is connected to an electrical conductor to be tested. Just as in the case of the voltage testing and display system described above, this voltage testing and display device comprises a voltage display for displaying the presence of a voltage in the electrical conductor, and a partial discharge detector for displaying partial discharges in the electrical conductor to be monitored. The device comprises a circuit impedance means which is provided for being connected on one side to the coupling capacitor and on the other side to a reference potential point, so that a voltage divider consisting of the coupling capacitor and the circuit impedance means is formed. in this case, according to the invention, the circuit impedance means consists either of a series connection of a capacitive coupling element and an ohmic resistor, or of a series connection of a capacitive coupling element and an inductor. The voltage display and the partial discharge detector each receive the same voltage, dropping across the circuit impedance means, as their measuring voltage, i.e., as their input measured variable.

In one embodiment, the voltage testing and display device may further comprise a voltage limiter for limiting the measuring voltage.

According to a further aspect of the invention, a voltage testing and display system is proposed, said system comprising a voltage testing and display device and a coupling capacitor, the voltage testing and display device being coupled to the electrical conductor via the coupling capacitor.

The invention will be described in more detail in the following, based on the figures. In the figures:

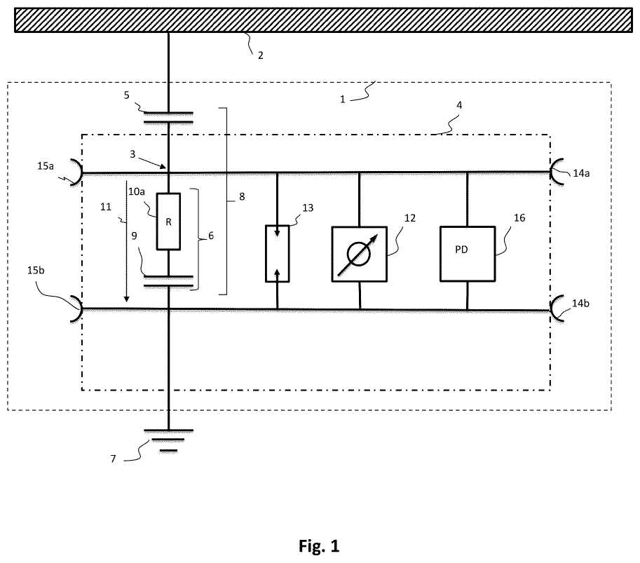

FIG. 1 shows an arrangement of a voltage testing and display system with an ohmic resistor in the circuit impedance means;

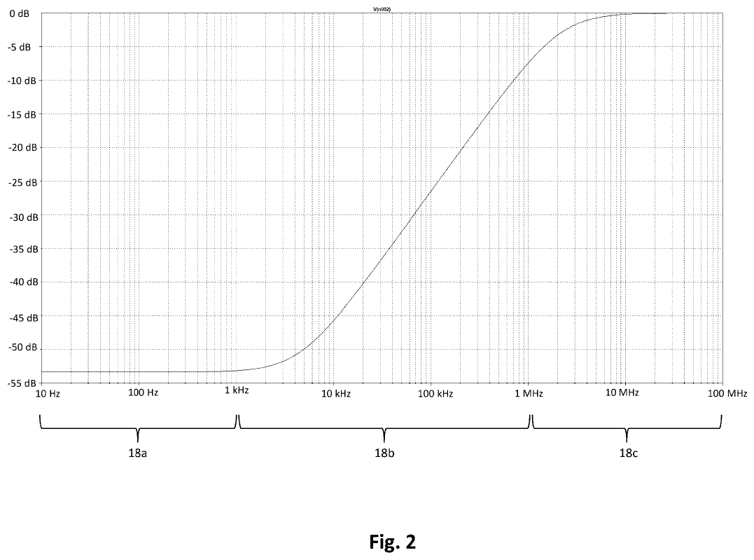

FIG. 2 shows a frequency response of the circuit impedance means with 10 Hz<f<100 MHz, which has an ohmic resistor;

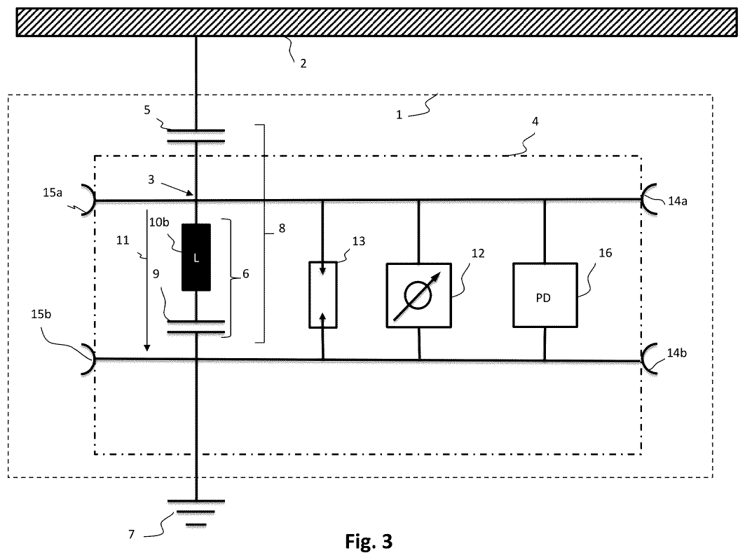

FIG. 3 shows an arrangement of a voltage testing and display system with an inductor in the circuit impedance means;

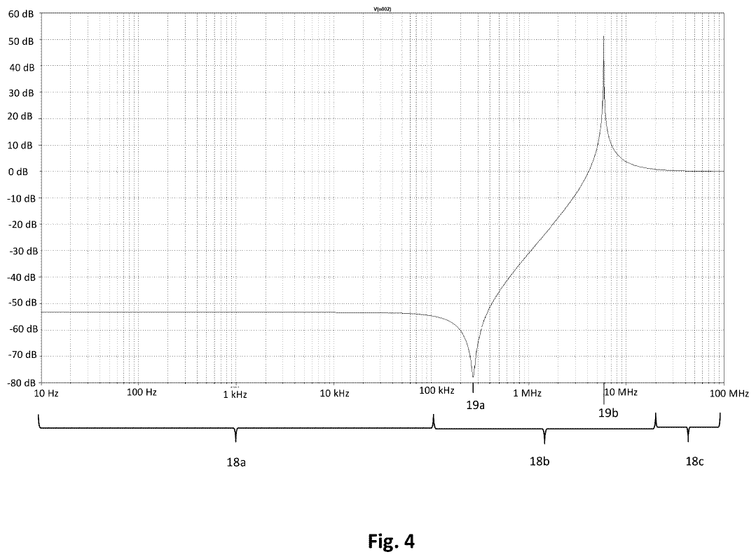

FIG. 4 shows a frequency response of the circuit impedance means with 10 Hz<f<100 MHz, which has an inductance.

FIG. 1 is a schematic circuit diagram of a voltage testing and display system 1, which is connected to an electrical conductor 2 and a reference potential point 3. In this case, the voltage testing and display system shown in FIG. 1 for a conductor 2 is representative of corresponding systems in three-phase voltage systems.

In this case, the electrical conductor 2 can be a cable for high or extra-high voltages and large currents, i.e., for voltages of more than 1000 volts. Alternatively, the conductor 2 can be a live element which is provided for a voltage level of less than 1000 volts, for example a rotating machine.

The voltage testing and display system 1 comprises a voltage testing and display device 4 and a coupling capacitor 5, the voltage testing and display device 4 being coupled to the electrical conductor 2 at a connection point 3 via the coupling capacitor 5. In this case, the voltage testing and display device 4 typically has a housing in which the circuit elements described below are arranged in a suitable manner. In this case, the displays for the voltage-free state of an electrical conductor to be monitored are typically located on the front side, while the electrical connection to a conductor to be monitored or a voltage, and the connection for a reference potential point, are located on the rear side of the housing.

In this case, the coupling capacitor 5 is typically arranged in a support or a feedthrough.

The voltage testing and display device 4 has a circuit impedance means 6 which is connected on one side to the coupling capacitor 5 and on the other side to a reference potential point 7, so that the voltage at the output of the coupling capacitor 5 is supplied to the voltage testing and display device 4 as an input signal. The reference potential point 7 is typically the ground potential point.

The circuit impedance means 6, together with the coupling capacitor 5, forms a voltage divider 8, a measuring voltage 11 dropping across the circuit impedance means 6. In this case, the elements of the voltage divider 8 are dimensioned such that the voltage of the electrical conductor 2 is divided down to a suitable measuring voltage 11, which is suitable as an input voltage for measuring instruments.

The voltage testing and display device 4 comprises a voltage display 12 for displaying the presence of a voltage, the voltage display 12 receiving the measuring voltage 11 as its input voltage, i.e., the voltage display 12 receives the voltage of the electrical conductor 2 divided by the division ratio of the voltage divider 8. In this case, the voltage display 12 shows the presence of a voltage on the electrical conductor 2 when it exceeds a configured limit value. Thus, the voltage display 12 shows whether the electrical conductor 2 is voltage-free or whether a voltage exceeding the configured limit value is applied to the electrical conductor 2.

In one embodiment, the voltage testing and display device 4 may include a voltage limiter 13 which is connected in parallel to the voltage display 12, i.e., which is arranged in parallel to the circuit impedance means 6. In this case, the voltage limiter can be a Zener diode, a varistor, or another suitable circuit element.

In one embodiment, the voltage testing and display device 4 comprises a front-side interface 14a-14b, at which it is possible to tap the reference potential point 7 at a connection 14b and the measuring voltage 11 at a connection 14a, for each connected electrical conductor 1.

Furthermore, the voltage testing and display device 4 can have an optional connection point 15a for tapping the measuring voltage, and a connection point 15b for tapping the reference potential point 7, on the rear side of the housing.

The voltage testing and display device 4 comprises a partial discharge detector 16, which, like the voltage display 12, receives the measuring voltage 11 dropping across the circuit impedance means 6 as an input signal. The partial discharge detector 16 is thus arranged in parallel to the voltage display 12. The partial discharge detector is designed to indicate high-frequency signals of partial discharges in the electrical conductor 2. Partial discharges in the electrical conductor 2, i.e., for example in its cable insulation, cause high-frequency and typically short-term current and voltage pulses in the electrical conductor 2, the voltage amplitude of which is small compared to the mains voltage. If such pulses are detected in the voltage of an electrical conductor, then it can be concluded from these that partial discharges are occurring, which damage and destroy the cable. These high-frequency pulses are superimposed on the mains voltage, which typically has a mains frequency of 16 ⅔ Hz or 50 Hz or 60 Hz.

While the voltage test in the voltage display 12 depends on the voltage at the mains frequency, the high-frequency pulses are relevant for the partial discharge detector 16. The partial discharge detector 16 is accordingly configured and designed to detect and display high-frequency voltage pulses in its input signal, i.e., the measuring voltage 11. In one embodiment, the partial discharge detector 16 continuously displays a partial discharge detected for an electrical conductor 2 after its detection, until the display is reset manually or remotely.

In a first embodiment, the circuit impedance means consists of an ohmic resistor 10a in series with a capacitive balancing element 9, so that the voltage display 12, just like the partial discharge detector 16, each receive the voltage, dropping across the ohmic resistor 10a and the capacitive balancing element 9, as an input signal.

In this embodiment, the voltage divider 8 consists of the coupling capacitor 5 and the circuit impedance means 6, which consists of the capacitive balancing element 9 and the frequency-independent ohmic resistor 10a.

FIG. 2 shows a schematic curve of the frequency response of a voltage divider 8, said voltage divider consisting of a coupling capacitor 5 and a circuit impedance means 6, which consists of an ohmic resistor 10 and a balancing capacitor 9.

Depending on the frequency, the attenuation of the measuring voltage 11 dropping across the circuit impedance means 6 in relation to the voltage dropping across the entire voltage divider is plotted in logarithmic representation for a frequency range from 10 Hz to 100 MHz. In this case, by way of example a value of C₁=7.5×10⁻¹² Farad was assumed for the coupling capacitor 5, a value of R=10 kΩ for the ohmic resistor 10, and a value of C₂=3500×10⁻¹² Farad for the capacitive balancing element 9. A person skilled in the art understands that the frequency response of the attenuation depends on the ratio of the selected parameters C₁ to C₂ and to R. Accordingly, it follows that the attenuation curve, i.e., the divider ratio of the voltage divider 8, can be set depending on the frequency.

The attenuation thus exhibits the frequency-dependent curve of the divider ratio of the voltage divider 8. The attenuation curve shows that the attenuation of the measuring voltage across the circuit impedance means 6 in a first frequency range 18a from 10 Hz to approximately 1 kHz is almost constant, at approximately −53 dB. In this range, with the values of C₁, C₂ and R selected here, the ratio of the capacitors is decisive for the divider ratio of the voltage divider, since the value of the ohmic resistor R for this first frequency range is very small and almost negligible here. For mains frequencies, i.e., for a range of 16.7 Hz to 60 Hz, the ratio of the capacitors is decisive with respect to the divider ratio of the voltage divider 8.

In a second frequency range 18b from approximately 1 kHz to approximately 1 MHz, the attenuation decreases to a value of approximately 7.5 dB, because at higher frequencies the absolute resistance values of the capacitors become smaller, whereas the resistance value of the ohmic resistor 10a is independent of the frequency and thus becomes more relevant.

For frequencies above 1 MHz, third range 18c, the attenuation then asymptotically approaches zero, it already being close to zero at approximately 10 MHz.

Since voltage pulses from partial discharges are high-frequency, i.e., typically have frequencies above 100 kHz, they are divided using the corresponding divider ratio. Since the absolute resistance values of the capacitors approach zero at high frequencies, while the ohmic resistor 10a in the voltage divider is independent of the frequency, almost the entire voltage drops across the ohmic resistor 10a and thus across the circuit impedance means at high frequencies.

For high-frequency partial discharge pulses, the absolute resistance values of the capacitors are almost negligible, so that no voltage of the partial discharge pulses drops across the capacitors and the voltage amplitude of the high-frequency partial discharge pulses is not divided down by the ratio of coupling capacitor to balancing capacitor. The voltage amplitude of high-frequency partial discharge pulses thus falls almost undamped across the ohmic resistor 10a and therefore across the circuit impedance means. Unlike a conventional purely capacitive voltage divider, which would divide down all voltages according to the ratio of the capacitors, regardless of the frequency, high-frequency partial discharge pulses do not need to be amplified here, but rather are available to the partial discharge detector 16 unattenuated as an input signal.

FIG. 3 shows an alternative arrangement of a voltage testing and display system 1.

Just like the embodiment shown in FIG. 1, this alternative voltage testing and display system 1 comprises a voltage testing and display device 4 and a coupling capacitor 5, the voltage testing and display device 4 being connected on one side via the coupling capacitor 5 to an electrical conductor 2, and on the other side to a reference potential point 7. This embodiment also includes a circuit impedance means 6, which connects the coupling capacitor 5 to the reference potential point 7, so that the circuit impedance means 6, together with the coupling capacitor 5, forms a voltage divider 8, a measuring voltage 11 dropping across the circuit impedance means 6. The voltage testing and display device 4 also has a voltage limiter 13 for limiting the measuring voltage 11, as well as a voltage display 12 and a partial discharge detector 16, each of which receives the measuring voltage 11 dropping across the circuit impedance means 6 as an input signal. Furthermore, in this embodiment, too, the circuit impedance means 6, the voltage limiter 13, the voltage display 12 and the partial discharge detector 16 can be arranged in a housing. Optionally, the front side of the housing can have a front-side tap 14b of the reference potential point 7 and the measuring voltage 14a. Accordingly, the reference potential point 7 and the measuring voltage 11 can also be provided on the rear side of the housing, at a rear-side connection point 15a.

The embodiment shown in FIG. 3 differs from the embodiment shown in FIG. 1 in that the circuit impedance means 6 consists of a series connection of a balancing capacitor 9 with an inductor 10b, so that the voltage divider 8 consists of the coupling capacitor 5 and the series connection of the capacitive balancing element 9 and the inductor 10b.

FIG. 4 shows the frequency response curve of the attenuation of the measuring voltage 11 dropping across the circuit impedance means 8, in relation to the voltage of the electrical conductor 2. Just as above with regard to In a first range 18a from 10 Hz to approximately 100 kHz, the attenuation is almost constant at approximately 53 dB. The divider ratio of the voltage divider 8 is constant in this range and is determined by the ratio of the capacitor values. The influence of the inductor 10b on the divider ratio is negligible in this frequency range.

In a second range 18b from approximately 100 kHz to approximately 11 MHz, the overall attenuation decreases, the curve having a first pole 19a at the resonant frequency of the inductor 10b with the capacitive tuning element 9, and a second pole 19b at the resonant frequency of the inductor 10b with the coupling capacitor 5. At the first pole 19a, i.e., at the resonant frequency of the inductive resistor 10b with the capacitive balancing element 9, the resistance across the series connection of the inductive resistor and the capacitive balancing element is almost zero, such that the entire voltage drops across coupling capacitor 5 and the attenuation increases significantly, to more than 70 dB with the values of the capacitive balancing element and the inductive resistor selected here.

For frequencies higher than the first resonant frequency, the attenuation initially decreases sharply, up to a second pole 19b, which results at the resonant frequency of the series connection of the inductive resistor with the capacitive balancing element, the attenuation increasing up to a value greater than zero. For the parameters selected here by way of example, the pole 19b results at the resonant frequency of approximately 5.63 MHz. Subsequently, i.e., for frequencies from the second pole 19b to approximately 11 MHz, the attenuation asymptotically approaches 0 dB, since at these high frequencies the resistances of the coupling capacitor and the capacitive balancing element approach zero, while the resistance value of the inductive resistor 10b increases with increasing frequency. For increasing frequencies, the total resistance of the circuit impedance means 6 thus increases, while the resistance value of the coupling capacitor 5 becomes ever smaller, such that almost the entire voltage across the voltage divider 8 drops exclusively across the circuit impedance means and the divider ratio and the attenuation remain almost at zero. High-frequency partial discharge pulses are therefore not divided down by the divider ratio of coupling capacitor 5 to capacitive balancing element 9, but rather are available to the partial discharge detector unattenuated.

The frequency-dependent behavior of the two embodiments of the circuit impedance means results in the divider ratio of the voltage divider 8 being determined, depending on the value of the ohmic resistor 10a or alternatively the inductive resistor, essentially by the ratio of the coupling capacitor 5 to the capacitive balancing element 9 for the typical mains frequencies below 100 Hz, whereas for higher frequency signals the divider ratio is determined by the ohmic resistor or by the inductive resistor, such that voltage pulses with less attenuation, caused by partial discharges, are provided to the partial discharge detector as an input signal.

### LIST OF REFERENCE SIGNS

1 voltage testing and display system
2 electrical conductor
3 connection point for coupling capacitor
4 voltage testing and display device
5 coupling capacitor
6 circuit impedance means
7 reference potential point, ground potential point
8 voltage divider
9 capacitive balancing element
10a ohmic resistor
10b inductive resistor
11 measuring voltage
12 voltage display
13 voltage limiter
14a front-side interface for measuring voltage
14b front-side tap of the reference potential point
15a rear-side connection point
15b rear-side tap of the reference potential point
16 partial discharge detector
17 attenuation at an ohmic resistor in the circuit impedance means
18a first frequency range
18b second frequency range
18c third frequency range
19a first pole
19b second pole

1. A voltage testing and display device for galvanic coupling to a coupling capacitor which is connected to an electrical conductor to be tested comprising:
a circuit impedance means which connects the coupling capacitor to a reference potential point, and
a voltage display for displaying the voltage of the electrical conductor,
the voltage display receiving the voltage dropping across the circuit impedance means as a measuring voltage, and
comprises a partial discharge detector for detecting partial discharges in the electrical conductor,
wherein the circuit impedance means consists of an ohmic resistor in series with a capacitive balancing element, or of an inductor in series with the capacitive balancing element, and
wherein the partial discharge detector receives the measuring voltage as an input signal.

2. The voltage testing and display device according to claim 1, wherein the voltage testing and display device is provided for voltages of more than 1000 volts.

3. The voltage testing and display device according to claim 1, wherein a ratio between the coupling capacitor and the capacitive balancing element is at least 10 and at most 1000.

4. The voltage testing and display device according to claim 1, wherein the voltage testing and display device has a housing and wherein the circuit impedance means and the voltage display and the partial discharge detector are arranged in the housing.

5. The voltage testing and display device according to claim 4, wherein the housing comprises a connection point for the measuring voltage on a front side.

6. The voltage testing and display device according to claim 1, wherein the voltage testing and display device has a voltage limiter which is arranged electrically in parallel to the circuit impedance means.

7. A voltage testing and display system comprising
a voltage testing and display device according to claim 1 and
a coupling capacitor, wherein the circuit impedance means of the voltage testing and display device is connected to an electrical conductor via the coupling capacitor.

8. The voltage testing and display device according to claim 2, wherein the voltage testing and display device has a housing and wherein the circuit impedance means and the voltage display and the partial discharge detector are arranged in the housing.

9. The voltage testing and display device according to claim 3, wherein the voltage testing and display device has a housing and wherein the circuit impedance means and the voltage display and the partial discharge detector are arranged in the housing.

10. A voltage testing and display system comprising
a voltage testing and display device according to claim 2 and a coupling capacitor, wherein the circuit impedance means of the voltage testing and display device is connected to an electrical conductor via the coupling capacitor.

11. A voltage testing and display system comprising
a voltage testing and display device according to claim 3 and a coupling capacitor, wherein the circuit impedance means of the voltage testing and display device is connected to an electrical conductor via the coupling capacitor.

12. A voltage testing and display system comprising
a voltage testing and display device according to claim 4 and a coupling capacitor, wherein the circuit impedance means of the voltage testing and display device is connected to an electrical conductor via the coupling capacitor.

13. A voltage testing and display system comprising
a voltage testing and display device according to claim 5 and a coupling capacitor, wherein the circuit impedance means of the voltage testing and display device is connected to an electrical conductor via the coupling capacitor.

14. A voltage testing and display system comprising
a voltage testing and display device according to claim 6 and a coupling capacitor, wherein the circuit impedance means of the voltage testing and display device is connected to an electrical conductor via the coupling capacitor.
